(19) United States
(12) Patent Application Publication
(10) Pub. No.: US 2009/0034202 A1
(43) Pub. Date: Feb. 5, 2009

(54) HEAT-DISSIPATING MODULE

(75) Inventors: Wei-Chuan Chiu, Taipei (TW); Yueh-Wen Wu, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTEK COMPUTER INC., Taipei (TW)

(21) Appl. No.: 12/137,543

(22) Filed: Jun. 12, 2008

(30) Foreign Application Priority Data
Aug. 3, 2007 (TW) 96128699

(51) Int. Cl. H05K 7/20

(52) U.S. Cl. 361/704

(57) ABSTRACT

A heat-dissipating module suitable for dissipating heat for a heat-generating element is provided. The heat-dissipating module includes a heat-dissipating base, a cooling fan having a case and a blades assembly disposed in the case, a heat pipe and a thermoelectric converter. The heat-dissipating base is disposed on the heat-generating element, and the case has an air inlet and an air outlet. The heat pipe is connected between the heat-dissipating base and the cooling fan, and the heat pipe has a first end connected to the heat-dissipating base and a second end disposed in the case adjacent to the air outlet. The thermoelectric converter is disposed on the second end, and the thermoelectric converter is suitable for converting a temperature difference between the second end and an environment near the air outlet into output electrical energy.

### CROSS-REFERENCE TO RELATED APPLICATION

This application claims the priority benefit of Taiwan application serial no. 96128699, filed on Aug. 3, 2007. The entirety of the above-mentioned patent application is hereby incorporated by reference herein and made a part of specification.

### BACKGROUND OF THE INVENTION

1. Field of the Invention

The invention relates to a heat-dissipating module and, more particularly, to a heat-dissipating module for a portable computer.

2. Description of the Related Art

In recent years, with the rapid development of the computer science and technology, the operation speed of the computer is continuously increased, so that the heat generating power of the electronic devices in the computer is also continuously increased. Take a notebook computer as an example, because of the fast operation speed of the working chip, much heat will be generated by the working chip. To effectively dissipate the heat generated by the working chip such as the central processing unit and make the working chip work in a normal state, in the prior art, a heat sink with a fan is usually assembled on the working chip, and the active airflow caused by the fan can remove the heat conducted from the working chip to the heat sink. Therefore, the heat from the working chip can be dissipated effectively.

With the continuous increase of the speed of the working chip, a bigger-sized heat sink is used, or the rotating speed of the fan is increased in the prior art to make the heat sink have a better heat-dissipating efficiency. However, the notebook computers on the market are all developed to be light and slim, and the inner space of the notebook computer is limited, so that a big-sized heat sink is difficult to be installed in the notebook computer whose inner space is limited. In addition, if the rotating speed of the fan is increased for good heat dissipation effect, the demand for electricity of the whole notebook computer will be increased, too. Thus the working hours of the notebook computer will be shortened.

### BRIEF SUMMARY OF THE INVENTION

The invention provides a heat-dissipating module which has a better heat dissipation efficiency.

The invention provides a heat-dissipating module suitable for dissipating the heat for a heat-generating element in a portable computer, and the portable computer can work for a longer time.

The invention provides a heat-dissipating module suitable for dissipating the heat for a heat-generating element in a portable computer. The heat-dissipating module includes a heat-dissipating base, a cooling fan, a heat pipe and a thermoelectric converter. The heat-dissipating base is provided on the heat-generating element. The cooling fan includes a case and a blades assembly which is installed in the case. The case has an air inlet and an air outlet. Besides, the heat pipe is connected between the heat-dissipating base and the cooling fan. The heat pipe includes a first end and a second end. The first end is connected to the heat-dissipating base, and the second end is located on a part of case adjacent to the air outlet. The heat generated by the heat-generating element can be conducted to the second end of the heat pipe via the heat-dissipating base. The thermoelectric converter is located on the second end, and the thermoelectric converter is suitable for converting a temperature difference between the second end and the ambient environment near the air outlet into an output electrical energy.

In the invention, the second end of the heat pipe is provided on a part of the case adjacent to the air output, and a thermoelectric converter is provided on the second end. Since the ambient environment near the air output has a preferred thermal convection effect, its temperature is lower than that of the second end of the heat pipe, and the thermoelectric converter can generate output electrical energy by the temperature gradient between the second end and the ambient environment near the air outlet. That is, besides the function of effectively dissipating the heat for the heat-generating elements, the heat-dissipating module of the present invention can also convert the heat energy into electrical energy to increase the working hours of the portable computer.

These and other features, aspects, and advantages of the present invention will become better understood with regard to the following description, appended claims, and accompanying drawings.

### BRIEF DESCRIPTION OF THE DRAWINGS

FIG. 1 is a three-dimensional diagram showing a heat-dissipating module provided on a heat-generating element of a portable computer of an embodiment of the present invention.

FIG. 2 is a circuit block diagram showing that the thermoelectric converter shown in FIG. 1 stores the generated output electrical energy into the battery.

FIG. 3 is a circuit block diagram showing that the thermoelectric converter shown in FIG. 1 supplies the generated output electrical energy to the electronic element.

### DETAILED DESCRIPTION OF THE EMBODIMENTS

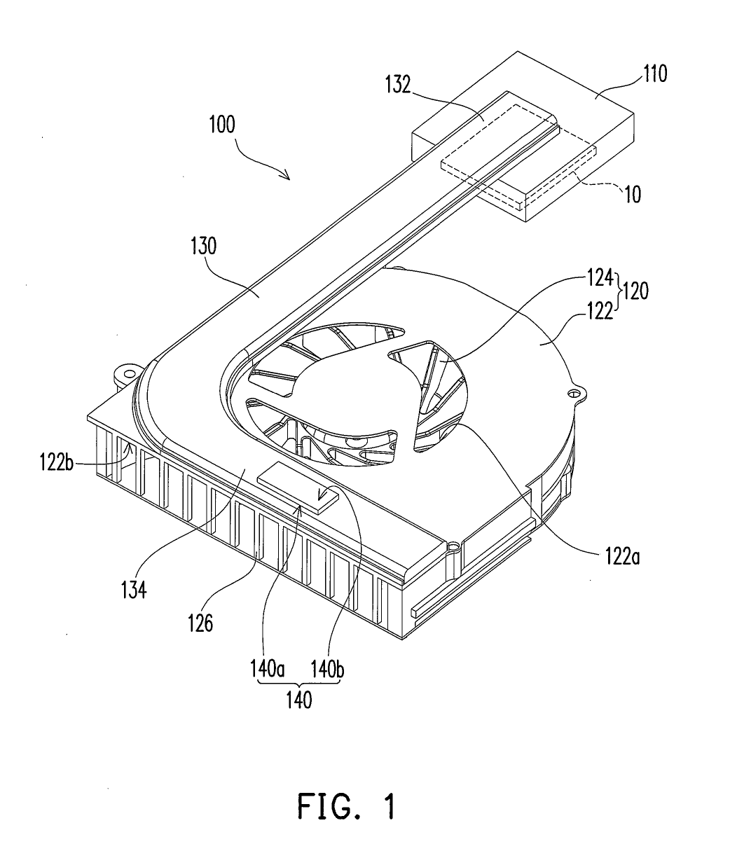

FIG. 1 is a three-dimensional diagram showing a heat-dissipating module provided on a heat-generating element of a portable computer of one embodiment of the invention. Please refer to FIG. 1. The heat-dissipating module 100 of the embodiment is provided on a heat-generating element 10 of a portable computer and used for dissipating the heat generated by the heat-generating element 10. In the embodiment, the heat-generating element 10, such as a central processing unit, a north bridge chip, a south bridge chip or other heat-generating element which generates much heat power in its working state. The heat-generating module 100 of the embodiment is suitable to be provided on the heat-generating element 10 to dissipate the heat for the heat-generating element 10 effectively, so that the portable computer can work in a normal state. A detailed description of the heat-generating module 100 is given as follows.

From the above, the heat-generating module 100 of the embodiment includes a heat-dissipating base 110, a cooling fan 120, a heat pipe 130 and a thermoelectric converter 140. The material of the heat-dissipating base 110 is copper or any other material having good heat conduction efficiency. The heat-dissipating base 110 is suitable to be connected to the heat-generating element 10. The cooling fan 120 is, for example, a centrifugal fan and includes a case 122 and a blades assembly 124 disposed in the case 122. The case 122 has an air inlet 122a and an air outlet 122b. When the cooling fan 120 is in the working state, the blades assembly 124 can rotate to drive the airflow to flow into the case 122 from the air inlet 122a and then flow out from the air outlet 122b.

Please keep on referring to FIG. 1. The heat pipe 130 in the embodiment is connected between the heat-dissipating base 110 and the cooling fan 120. In details, the heat pipe 130 includes a first end 132 and a second end 134. The first end 132 is connected to the heat-dissipating base 110, and the second end 134 is provided on a part of the case 122 adjacent to the air outlet 122b. The heat generated by the heat-generating element 10 can be conducted to the second end 134 of the heat pipe 130 via the heat-dissipating base 110. Since the second end 134 is provided on a part of the case 122 adjacent to the air out let 122b, and the material of the case 122 is metal having a good heat conduction efficiency, when the airflow generated by the blades assembly 124 flows through the air outlet 122b of the case 122, the airflow can remove the heat conducted to the case 122 from the second end 134 effectively.

Besides, part of the heat pipe 130 between the first end 132 and the second end 134 can be, for example, connected to the case 122. Since the case 122 has a bigger area for exchanging the heat, the heat generated by the heat-generating element 10 can be conducted to the case 122 via the heat pipe 130 and then can be convected to the outer environment via the case 122. In addition, a plurality of heat conduction pillars 126 can be provided at the air outlet 122b of the cooling fan 120, and when the airflow generated by the blades assembly 124 flows through the air outlet 122b, the heat conducted to the heat conduction post 126 from the case 122 can be removed directly.

In addition, the thermoelectric converter 140 in the embodiment is provided at the second end 134 of the heat pipe 130. Since the ambient environment of the air outlet 122b has a preferred heat convection effect, and the second end 134 of the heat pipe 130 is on the part of the case 122 adjacent to the air outlet 122b, the thermoelectric converter 140 provided on the second end 134 can convert the temperature difference between the second end 134 and ambient environment of the air outlet 122b into output electrical energy (which is called the Seebeck Effect).

More specifically, the thermoelectric converter 140 is, for example, composed of a P-type Semiconductor and an N-type Semiconductor. Wherein the first surface 140a of the thermoelectric converter 140 is connected to the second end 134 of the heat pipe 130, and the second surface 140b corresponding to the first surface 140a is exposed to an environment with a preferred convection effect. Affected by the second end 134, the first surface 140a has a higher temperature. Compared with the high temperature of the first surface 140a, the second surface 140b has a lower temperature by being exposed to the environment with a preferred convection effect. Therefore, the temperature difference between the first surface 140a and the second surface 140b forms a temperature gradient, and the thermoelectric converting module 140 can utilize the temperature gradient between the first surface 140a and the second surface 140b to generate the output electricity energy. In other words, in the embodiment, the heat-dissipating module 100 not only can dissipate the heat for the heat-generating element 10 effectively, but also can convert the heat energy generated by the heat-generating element 10 to the electrical energy which can be used for increasing the working hours of the portable computer.

Certainly, in other preferred embodiments, the first surface 140a of the thermoelectric converter 140 can also be attached on the first end 132, and the second surface 140b of the thermoelectric converter 140 can be exposed to the outer environment, so that the temperature gradient between the first surface 140a and the second surface 140b can be used to generate the output electrical energy. More specifically, as long as the first surface 140a is attached to an object with higher temperature, and the second surface 140b is exposed to the outer environment with a preferred heat convection effect, such thermoelectric converter 140 is within the spirit and scope of the invention, and it is not limited herein.

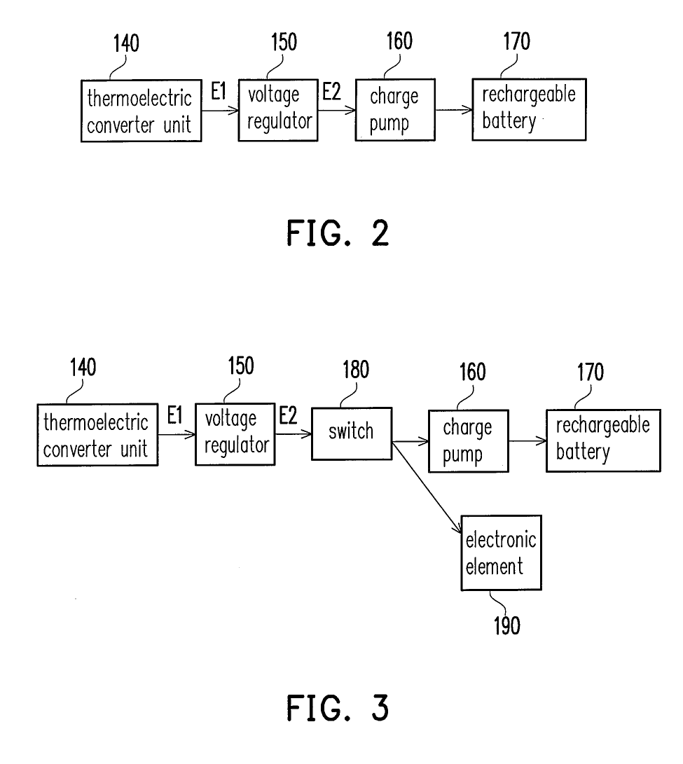

In the embodiment, the output electrical energy generated by the thermoelectric converter 140 can be stored in the battery of the portable computer. FIG. 2 is a circuit block diagram showing that the thermoelectric converter shown in FIG. 1 stores the output electrical energy into the battery. Please refer to FIG. 2. The portable computer of the present embodiment includes a voltage regulator 150, a charge pump 160 and a rechargeable battery 170 for storing the output electrical energy. Wherein the output electrical energy E1 generated by the thermoelectric converter 140 can be converted into a stabilized power supply E2 via the voltage regulator 150, and then the charge pump 160 regulates (boosts) the stabilized power supply E2 outputted from the voltage regulator 150 to a predetermined voltage level, and then the stabilized power supply E2 having a predetermined voltage level can charge the rechargeable battery 170.

On the other hand, a switch 180 can be provided between the voltage regulator 150 and the charge pump 160, and the switch 180 can switch the stabilized power supply E2 outputted from the voltage regulator 150 into other electronic element 190 having a lower power such as a backlighting source of a keyboard, a cooling fan of a heat-dissipating module and so on (please refer to FIG. 3, which is a circuit block diagram showing that the thermoelectric converter shown in FIG. 1 supplies the generated output electrical energy to the electronic element).

To sum up, in the embodiment of the invention, the second end of the heat pipe is provided at part of the case near the air output, and a thermoelectric converter is disposed on the second end. Wherein, affected by the second end, the first surface of the thermoelectric converter has a higher temperature. Relatively, since the ambient environment of the air outlet has a preferred heat convection effect, the second surface which is exposed to an outer environment with a preferred heat convection effect has a lower temperature. Such that the thermoelectric converter of the embodiment of the invention can utilize the temperature gradient between the first surface and the second surface to generate the output electrical energy to supply to the battery or other electronic element of a portable computer. That is to say, the heat-dissipating module in the embodiment of the invention not only can dissipate the heat for the heat-generating element effectively, but also can convert the heat energy generated by the heat-generating element into electrical energy which can be used to increase the working hours of the portable computer.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A heat-dissipating module which is suitable to dissipate heat for a heat-generating element in a portable computer, the heat-dissipating module comprising:
a heat-dissipating base provided on the heat-generating element;
a cooling fan having a case and a blades assembly provided in the case, wherein the case has an air inlet and an air outlet;
a heat pipe connected between the heat-dissipating base and the cooling fan and having a first end connected to the heat-dissipating base and a second end provided on part of the case adjacent to the air outlet, wherein the heat generated by the heat-generating element can be conducted to the second end of the heat pipe via the heat-dissipating base; and
a thermoelectric converter provided on the second end, wherein the thermoelectric converter converts a temperature difference between the second end and an ambient environment of the air outlet into output electrical energy.

2. The heat-dissipating module according to claim 1, wherein the cooling fan is a centrifugal fan.

3. The heat-dissipating module according to claim 1, wherein part of the heat pipe between the first end and the second end is connected to the case.

4. The heat-dissipating module according to claim 1, wherein the material of the case is metal.

5. The heat-dissipating module according to claim 1, wherein the material of the heat-dissipating base is copper.

6. The heat-dissipating module according to claim 1, wherein the portable computer comprises a voltage regulator for converting the output electrical energy into a stabilized power supply.

7. The heat-dissipating module according to claim 6, wherein the portable computer further comprises a switch for switching the stabilized power supply outputted from the voltage regulator.

8. The heat-dissipating module according to claim 6, wherein the portable computer further comprises a charge pump for adjusting the voltage level of the stabilized power supply outputted from the voltage regulator.

9. The heat-dissipating module according to claim 1, wherein the portable computer further comprises a rechargeable battery for storing the output electrical energy.
